(19) United States
(12) Patent Application Publication
(10) Pub. No.: US 2025/0053195 A1
(43) Pub. Date: Feb. 13, 2025

(54) DISPLAY DEVICE AND METHOD OF MANUFACTURING THE SAME

(71) Applicant: SAMSUNG DISPLAY CO., LTD., YONGIN-SI (KR)

(72) Inventors: TECK SOO KIM, Yongin-si (KR); JUNG A LEE, Yongin-si (KR)

(21) Appl. No.: 18/594,045

(22) Filed: Mar. 4, 2024

(30) Foreign Application Priority Data
Aug. 9, 2023 (KR) 10-2023-0104145

(51) Int. Cl. G06F 1/16

(52) U.S. Cl. CPC G06F 1/163; G06F 1/1654

(57) ABSTRACT

A display device comprises a display panel, a window member disposed on the display panel, and an alignment mark layer disposed on a lower surface of the window member. The alignment mark layer comprises a light blocking layer disposed on the lower surface of the window member, and a pattern layer disposed on the light blocking layer. The pattern layer includes a through hole penetrating the pattern layer and exposing the light blocking layer.

### CROSS-REFERENCE TO RELATED APPLICATION

This application claims priority from to Korean Patent Application No. 10-2023-0104145, filed on Aug. 9, 2023, in the Korean Intellectual Property Office, the disclosure of which is incorporated by reference herein in its entirety.

### BACKGROUND

The present disclosure relates to a display device, and more particularly, to a display device capable of improving identification of alignment marks and a method of manufacturing the same.

The contemporary landscape of electronic devices encompasses a wide array of multimedia platforms being developed, including televisions, mobile phones, navigation systems, computer monitors, and game consoles. These electronic devices rely on display panels for image presentation. In particular, portable electronic devices, such as mobile phones and tablets are being developed. Furthermore, there is a trend in the development of display devices designed to work together with these portable electronic devices.

### SUMMARY

Aspects of the present disclosure provide a display device capable of improving identification of an alignment mark and a method of manufacturing the same.

According to embodiments of the present disclosure, a display device comprises a display panel, a window member disposed on the display panel, and an alignment mark layer disposed on a lower surface of the window member. The alignment mark layer comprises a light blocking layer disposed on the lower surface of the window member, and a pattern layer disposed on the light blocking layer. The pattern layer includes a through hole penetrating the pattern layer and exposing the light blocking layer.

In an embodiment, the light blocking layer comprises a plurality of layers.

In an embodiment, the light blocking layer comprises: a first light blocking layer disposed on the lower surface of the window member; and a second light blocking layer disposed on the first light blocking layer.

In an embodiment, a width of the second light blocking layer is smaller than a width of the first light blocking layer.

In an embodiment, a width of the pattern layer is smaller than the width of the second light blocking layer.

In an embodiment, a color of the light blocking layer and a color of the pattern layer are different from each other.

In an embodiment, the light blocking layer has a black-based color, and the pattern layer has a white-based color.

In an embodiment, an alignment mark of the alignment mark layer comprises a light blocking layer exposed through a through hole of the pattern layer.

In an embodiment, the alignment mark has one shape among a “¬” shape, a cross shape, a rectangular shape, a “T” shape and an “L” shape.

In an embodiment, from a plan view, the through hole forms a closed curve shape.

In an embodiment, an alignment mark of the alignment mark layer comprises a first and second marks disposed on different layers, wherein the first mark comprises a light blocking layer exposed by a through hole having a closed curve shape, and wherein the second mark comprises a pattern layer exposed surrounded and delineated by a through hole having a closed curve shape.

In an embodiment, the first and second marks each have one shape among a “¬” shape, a cross shape, a rectangular shape, a “T” shape and an “L” shape.

In an embodiment, the light blocking layer comprises a carbon-based light blocking material such as carbon black, a dye, a pigment, or a combination thereof.

In an embodiment, the pattern layer is formed of ink comprising a material, pigment, or dye of white color.

In an embodiment, the alignment mark layer further comprises a cover layer disposed on the pattern layer.

In an embodiment, the cover layer includes transparent SiO₂.

In an embodiment, the window member comprises: a body portion on which the display panel is disposed; and a flange portion disposed on the edge of the body portion.

In an embodiment, the alignment mark layer is disposed on the lower surface of the flange portion.

According to embodiments of the present disclosure, a method of manufacturing a display device comprises disposing a first light blocking layer on a lower surface of the window member, disposing a second light blocking layer on the first light blocking layer, disposing a pattern layer on the second light blocking layer, and forming an alignment mark by forming a through hole in the pattern layer to expose the second light blocking layer.

In an embodiment, first and second light blocking layers each have black color, and wherein the pattern layer has white color.

In an embodiment, the alignment mark comprises a light blocking layer exposed through the through hole of the pattern layer.

In an embodiment, from a plan view, the through hole may form a closed curve shape.

In an embodiment, the alignment mark comprises first and second marks disposed on different layers, wherein the first mark comprises a light blocking layer exposed by the through hole having a closed curve shape, and wherein the second mark comprises a pattern layer surrounded and delineated by the through hole having a closed curve shape.

In an embodiment, forming the through hole in the pattern layer is performed with a laser beam

In an embodiment, the method further comprising disposing a cover layer on the pattern layer.

In an embodiment, the method further comprising aligning the window member and the display panel based on the alignment mark; and attaching the window member and the display panel.

In the display device and the method of manufacturing the same according to the present disclosure, a recognition rate of alignment marks can be improved.

In addition, since a pattern layer is patterned by a laser beam, alignment marks can be miniaturized and be made more precise.

According to embodiments of the present disclosure, a method of manufacturing a display device comprises disposing a first light blocking layer on a lower surface of a window member on a display panel; disposing a second light blocking layer on the first light blocking layer; disposing a pattern layer on the second light blocking layer; forming an alignment mark by forming a through hole in the pattern layer to expose the second light blocking layer; and applying a cover layer on the pattern layer.

The effects of the present disclosure are not limited to the above-described effects and other effects which are not described herein will become apparent to those skilled in the art from the following description.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a perspective view of a display device according to one embodiment;

FIG. 2 is a block diagram of a watch assembly of FIG. 1;

FIG. 3 is a plan view of a display device according to one embodiment;

FIG. 4 is a cross-sectional view taken along line I-I′ of FIG. 3;

FIG. 5 is a detailed view of portion A of FIG. 4 and FIG. 6 is a plan view of FIG. 5 viewed from a direction of a first arrow;

FIG. 7 is a cross-sectional view taken along line II-II′ of FIG. 6;

FIG. 8 is a cross-sectional view of a display device according to one embodiment;

FIG. 9 is a plan view of FIG. 8 viewed from a direction of a second arrow;

FIG. 10 is a plan view of an alignment mark layer of a display device according to one embodiment;

FIG. 11 is a plan view of an alignment mark layer of a display device according to one embodiment;

FIG. 12 is a plan view of an alignment mark layer of a display device according to one embodiment;

FIG. 13 is a plan view of an alignment mark layer of a display device according to one embodiment;

FIG. 14 is a plan view of an alignment mark layer of a display device according to one embodiment;

FIG. 15 is a plan view of an alignment mark layer of a display device according to one embodiment;

FIG. 16 is a plan view of an alignment mark layer of a display device according to one embodiment;

FIG. 17 is a plan view of an alignment mark layer of a display device according to one embodiment;

FIG. 18 is a plan view of an alignment mark layer of a display device according to one embodiment;

FIG. 19 is a diagram illustrating a lower surface of a display device according to one embodiment; and

FIGS. 20 to 25 are cross-sectional views for describing processes of a manufacturing method of an alignment mark layer of a display device according to one embodiment.

### DETAILED DESCRIPTION OF THE EMBODIMENTS

The present invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art.

It will also be understood that when a layer is referred to as being “on” another layer or substrate, it can be directly on the other layer or substrate, or intervening layers may also be present. The same reference numbers indicate the same components throughout the specification. In the attached figures, the thickness of layers and regions is exaggerated for clarity.

Terms such as “first”, “second”, etc. may be used herein to describe various elements, whereas these elements should not be limited by these terms. These terms may be used to distinguish one element from another element. Thus, a first element discussed below may be termed a second element without departing from teachings of one or more embodiments. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

Embodiments of the present disclosure may be combined partially or totally. As will be clearly appreciated by those skilled in the art, technically various interactions and operations are possible. Various embodiments can be practiced individually or in combination.

Hereinafter, exemplary embodiments will be described with reference to the accompanying drawings.

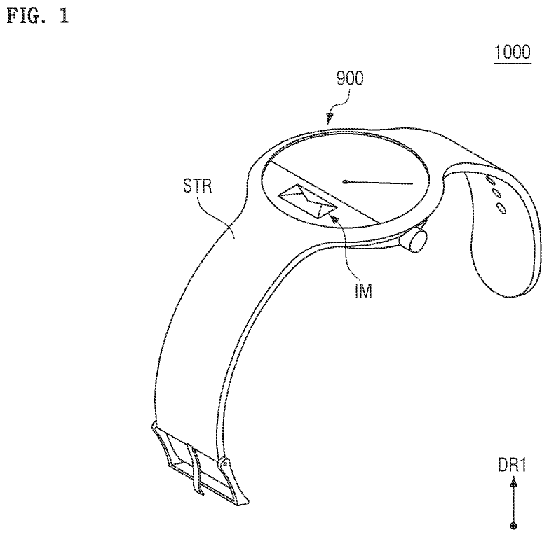

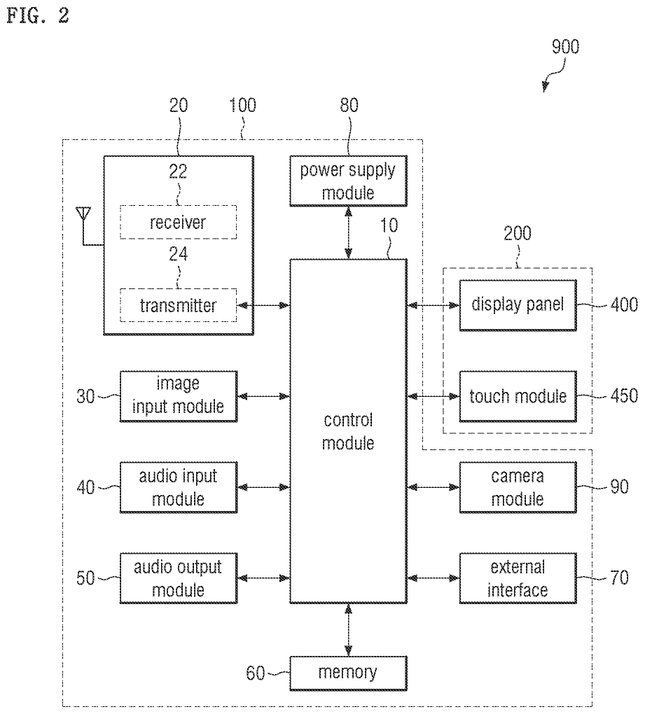

FIG. 1 is a perspective view of a display device according to one embodiment. FIG. 2 is a block diagram of a watch assembly of FIG. 1. Hereinafter, a display device according to one embodiment will be described referring to FIGS. 1 and 2.

Referring to FIG. 1, a display device 1000 according to one embodiment may be a watch. In addition, the display device according to one embodiment may not only be a watch but may be a device capable of displaying an image such as mobile phones, tablets, monitors, head-mount display devices or televisions.

The display device 1000 may be a watch as illustrated in FIG. 1. The display device 1000 may include a watch assembly 900 and a strap STR. The watch assembly 900 may display an image IM, which includes predetermined information, oriented in a first direction DR1. Herein, the first direction DR1 may be referred to as a vertical direction or a thickness direction. In some examples, the image IM may display an image indicating an analog clock, such as a clock hand displaying the current time. In some examples, the image IM may display an icon of an application running on an application processor or an execution screen of the application.

The watch assembly 900 may be attached and detached from the strap STR. This allows the user to wear the display device conveniently on the wrist or potentially elsewhere, depending on the design of the strap or other carrying mechanisms. A user may wear a strap STR on his or her wrist to use the display device 1000 (e.g., an electronic watch) on the wrist. The strap STR is not limited to the purpose of being worn on the user's wrist. The strap STR may be modified to be worn on the user's arm or worn around the neck, and can be replaced with a watch cradle for mounting the watch assembly 900 to another electronic device.

As shown in FIG. 2, the watch assembly 900 may include a display module 200 and an electronic module 100. The display module 200 may include a display panel 400 and a touch module 450. In one embodiment, the touch module 450 may be optional. In some examples, the touch module 450 may be integrated into the display module 200, providing interactive capabilities directly on the screen. In some examples, the touch module 450 may be replaced with a keypad or similar input devices for different user interface options.

The display module 200 may generate the image IM shown in FIG. 1. The display module 200 may include an organic light emitting display panel, a liquid crystal display panel, an electrophoretic display panel, and the like. The touch module 450 may detect external input. External input applied to the touch module 450 can be recognized as either direct touch or proximity sensing, such as hovering, triggered by an external object like a user's finger or a stylus pen. This allows the device to interpret various forms of user interaction, accommodating both contact and near-contact gestures. The type of the touch module 450 is not limited, and may be a capacitive touch module, a sound wave touch module, or an optical touch module.

The electronic module 100 may include various functional modules for operating the watch assembly 900. The electronic module 100 may include at least one of a control module 10, a wireless communication module 20, an image input module 30, an audio input module 40, an audio output module 50, a memory 60, an external interface 70, a power supply module 80, and a camera module 90. The modules may be affixed onto a printed circuit substrate and interconnected electrically through a flexible circuit substrate.

The control module 10 may control the overall operation of the display device 1000, including managing data processing tasks. For example, the control module 10 may activate or deactivate the display module 200 and output input image data to the display module 200. The control module 10 activates or deactivates the touch module 450 and controls the display module 200, the image input module 30, the audio input module 40, and audio output module 50 and the like based on the touch signal received from the touch module 450.

The wireless communication module 20 may transmit wireless signals to and receive wireless signals from other terminals using a Bluetooth or Wi-Fi connectivity. The wireless communication module 20 may transmit and receive audio signals using a general communication connectivity. The wireless communication module 20 may include a transmitter 24 that modulates and transmits a signal to be transmitted, and a receiver 22 that demodulates the received signal.

The image input module 30 may process the input image data and convert the input image data into an image data that can be displayed on the display module 200. The audio input module 40 may receive an external audio signal through a microphone in a recording mode, voice recognition mode, or the like and convert the audio signal into electrical audio data. The audio output module 50 may convert the audio data received from the wireless communication module 20 or the audio data stored in the memory 60 and output the audio data to the external.

The external interface 70 may serve as an interface connected to an external charger, a wired or a wireless data port, a card socket (e.g., memory card, SIM/UIM card), or the like. The power supply module 80 may supply power required for the overall operation of the watch assembly 900.

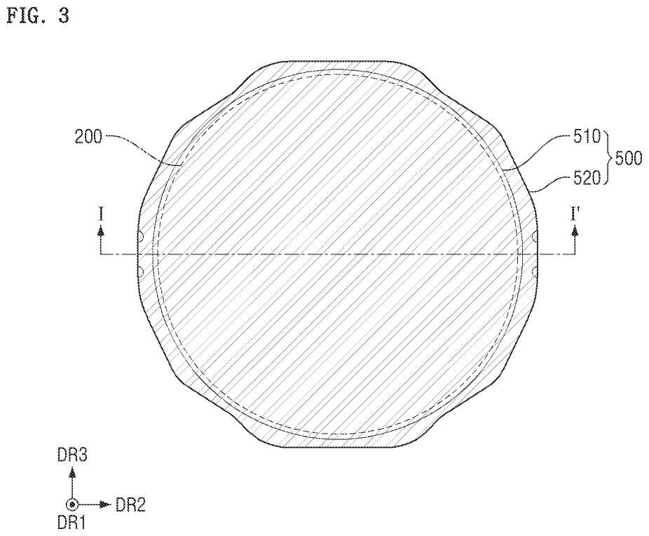

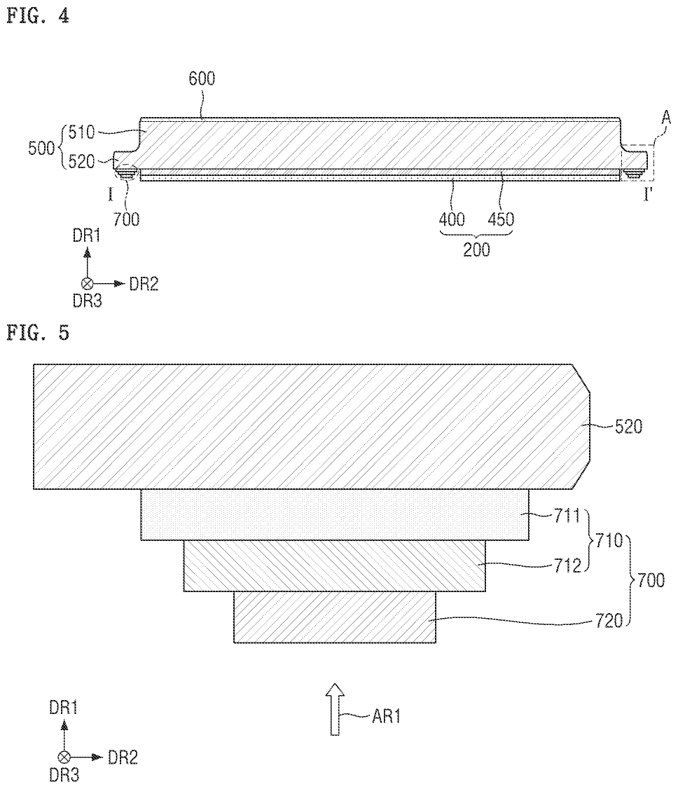

FIG. 3 is a plan view of a display device according to one embodiment, and FIG. 4 is a cross-sectional view taken along line I-I′ of FIG. 3.

As illustrated in FIGS. 3 and 4, the display device according to one embodiment may include a display panel 400, a window member 500, an anti-fingerprint film 600 and an alignment mark layer 700.

The display module 200 may display an image. For example, the display module 200 may display an image indicating pre-determined information, oriented in the first direction DR1.

The window member 500 may be disposed on the display module 200. For example, the display module 200 may include a display panel 400 and a touch module 450 on the display panel 400, and the window member 500 may be disposed on the touch module 450. For example, the touch module 450 may be disposed between the display panel 400 and the window member 500. The window member 500 may be attached to the display module 200 through an adhesive member. For example, the window member 500 may be attached to the touch module 450 of the display module 200 through the adhesive member. The window member 500 may be made of a transparent material that can transmit images from the display panel 400. For example, the window member 500 may include various materials, ranging from rigid options such as glass to flexible options such as transparent polymers.

The window member 500 may include a body portion 510 and a flange portion 520. The body portion 510 is disposed as a central body portion and the flange portion 520 is disposed as an adjoining flange portion. Both the body portion 510 and the flange portion 520 may be integrally formed and manufactured as a single, unified structure to enhance durability and streamline the design.

The body portion 510 of the window member 500 may have a circular shape in plan view, but the present disclosure is not limited thereto.

The flange portion 520 of the window member 500 may be disposed at the edge of the body portion 510. For example, the flange portion 520 may be disposed along the outer peripheral surface of the body portion 510. The flange portion 520 may have a ring shape. The thickness of the flange portion 520 may be smaller than the thickness of the body portion 510. Here, the thickness may mean the size in the first direction DR1.

The anti-fingerprint film 600 may inhibit the adherence of fingerprints on the surface of the window member 500, effectively minimizing residue from fingers or similar contact objects. The anti-fingerprint film 600 may be disposed on the upper surface of the window member 500. For example, the anti-fingerprint film 600 may be disposed on the body portion 510 of the window member 500. For example, the anti-fingerprint film 600 may be disposed on the upper surface of the body portion 510.

The alignment mark layer 700 may be a mark for alignment between the window member 500 and the display panel 400 to be attached to the window member 500. For example, the alignment mark layer 700 provides a guide for accurately positioning the window member 500 relative to the display panel 400 it will be attached to. The alignment mark layer 700 may be disposed at the edge of the window member 500. For example, the alignment mark layer 700 may located along the periphery of the window member 500, specifically on the underside of its flange portion 520. For example, the alignment mark layer 700 may be disposed on the lower surface of the flange portion 520 of the window member 500. In one embodiment, the alignment mark layer 700 may be disposed on the lower surface of the flange portion 520 and along the flange portion 520.

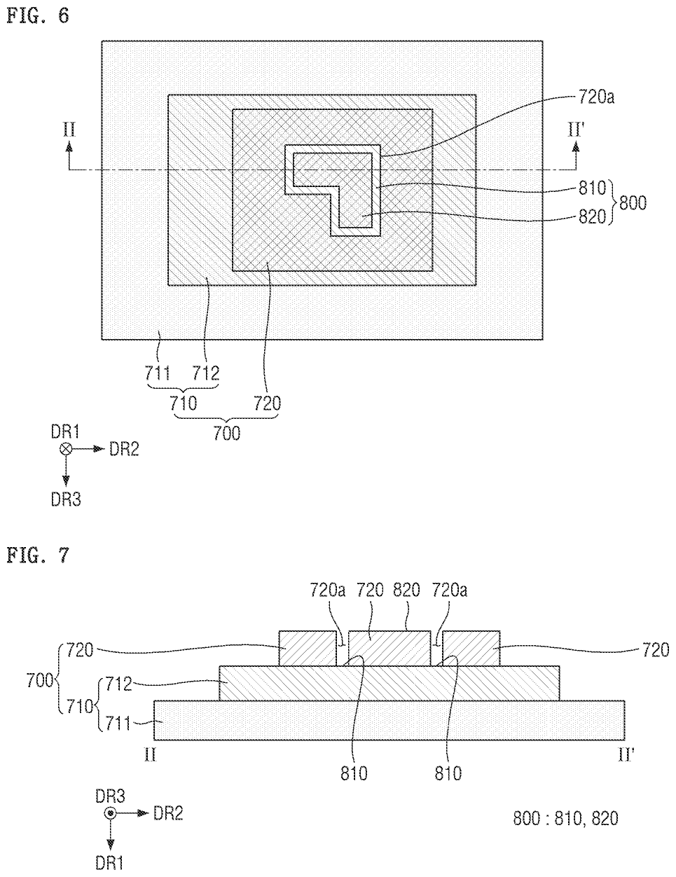

FIG. 5 is a detailed view of portion A of FIG. 4, FIG. 6 is a plan view of FIG. 5 viewed from a direction of a first arrow AR1, and FIG. 7 is a cross-sectional view taken along line II-II′ of FIG. 6.

As illustrated in FIG. 5, the alignment mark layer 700 may include a light blocking layer 710 and a pattern layer 720.

The light blocking layer 710 may be disposed on the lower surface of the flange portion 520. A first light blocking layer 711 may include a light blocking material. For example, the light blocking layer 710 may include carbon-based materials effective in obstructing light, including but not limited to carbon black, various dyes, or pigments, or a combination thereof. The light blocking material 710 may be dispersed within the binder polymer. For example, the light blocking layer 710 may be formed using a black matrix composition well known in the display field.

According to one embodiment, the light blocking layer 710 may have a multi-layer structure. For example, the light blocking layer 710 may include a first light blocking layer 711 and a second light blocking layer 712 sequentially stacked on the lower surface of the flange portion 520 along the reverse direction of the first direction DR1 (hereinafter, first reverse direction). As the light blocking layer 710 has a multi-layer structure, the cumulative thickness of the light blocking layer 710 increases, thereby improving the light blocking rate.

The first light blocking layer 711 may be disposed on the lower surface of the flange portion 520. The first light blocking layer 711 may include the light blocking material described above.

The second light blocking layer 712 may be disposed on the first light blocking layer 711. The second light blocking layer 712 may include the light blocking material described above. The width of the second light blocking layer 712 may be different from the width of the first light blocking layer 711. For example, the width of the second light blocking layer 712 may be smaller than the width of the first light blocking layer 711. Here, the width may refer to the size in a second direction DR2. Additionally, the length of the second light blocking layer 712 may be smaller than the width of the first light blocking layer 711. Here, the length may refer to the size in a third direction DR3.

Meanwhile, the color of the first light blocking layer 711 and the color of the second light blocking layer 712 may be different. For example, the first light blocking layer 711 may have a darker black color than the second light blocking layer 712.

The pattern layer 720 may be disposed on the second light blocking layer 712. The pattern layer 720 may include a material of contrasting color in contrast to the color of the light blocking layer 710, such as white, to effectively differ from the light blocking layer 710. For example, the pattern layer 720 may include a material, pigment, dye of white color, or a combination thereof. In one embodiment, the pattern layer 720 may be made of ink containing a material, pigment, or dye of white color. Meanwhile, the width of the pattern layer 720 may be smaller than the width of the second light blocking layer 712. Additionally, the length of the pattern layer 720 may be shorter than the length of the second light blocking layer 712. Meanwhile, the pattern layer 720 may have, for example, a square shape, but is not limited thereto.

As illustrated in FIGS. 6 and 7, the alignment mark layer 700 may define an alignment mark 800.

The alignment mark 800 may include a first mark 810 and a second mark 820. The first mark 810 and the second mark 820 may be disposed on different layers.

The first mark 810 and the second mark 820 of the alignment mark 800 may be delineated by a through hole 720a penetrating the pattern layer 720, and the detailed descriptions of the above with reference to FIGS. 6 and 7 are as follows.

As illustrated in FIGS. 6 and 7, the second light blocking layer 712 is adjacent to the pattern layer 720 in the first direction DR1. The second light blocking layer 712 may become visible through the through hole 720a of the pattern layer. The portion of the second light blocking layer that is exposed through this through hole may constitute the first mark 810. For example, the first mark 810 may include the second light blocking layer 712 exposed by the through hole 720a having a closed curve shape.

The first mark 810 may be formed in an engraved shape. For example, the mark is cut or carved directly into the surface, providing a distinct, recessed pattern for precise alignment.

Meanwhile, from a plan view as illustrated in FIG. 6, the through hole 720a may have a closed curve shape. The second mark 820 may be delineated by being surrounded by a through hole 720a from a plan view. For example, the second mark 820 may include a pattern layer 720 surrounded and delineated by the through hole 720a having a closed curve shape. At this time, the through hole 720a may define the outline of the second mark 820. For example, when the through hole 720a forms an “¬” shaped closed curve from a planar perspective as illustrated in FIG. 6, the second mark 820 surrounded by the through hole 720a may also have an “¬” shaped closed curve. The second mark 820 may be formed in an embossed shape. For example, the second mark 820 may be raised above the surrounding surface, creating a distinct, tactile pattern that is integral for accurate alignment and identification.

According to one embodiment, since the color (e.g., black) of the second light blocking layer 712 and the color (e.g., white) of the pattern layer 720 have high contrast, the identification of the first mark 810 exposed through the through hole 720a may be improved. Additionally, for the same reason, the identification of the second mark 820 (e.g., the second mark 820 in white color) surrounded by the first mark 810 (e.g., the first mark 810 in black color) may also be improved. Accordingly, the identification of the alignment mark 800 including the first mark 810 and the second mark 820 may be improved.

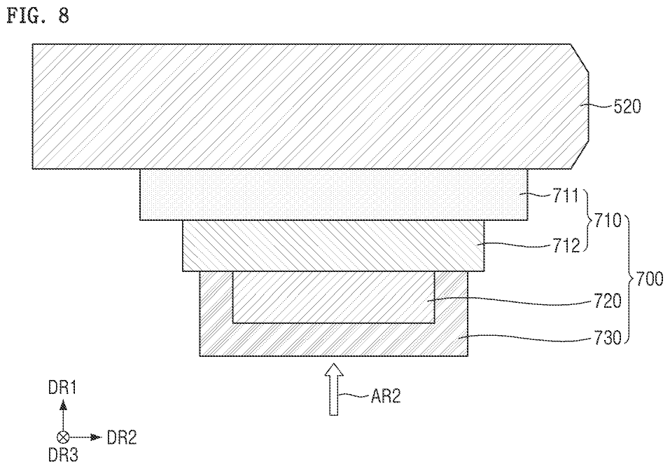

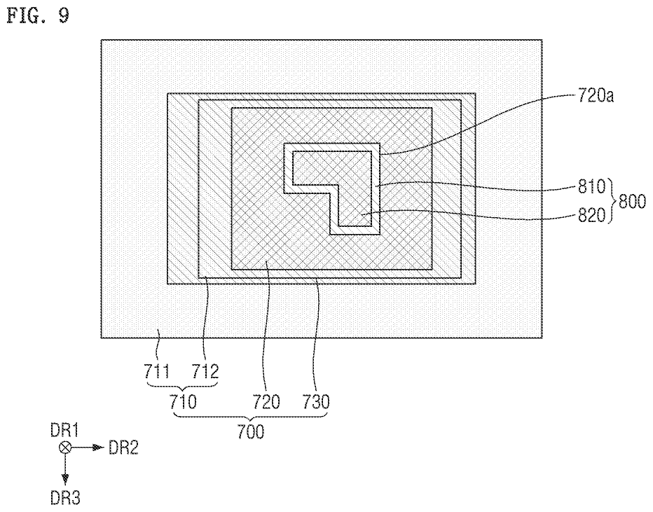

FIG. 8 is a cross-sectional view of a display device according to one embodiment, and FIG. 9 is a plan view of FIG. 8 viewed from a direction of a second arrow AR2. Here, FIG. 8 may be a detailed view of portion A of FIG. 4 according to another embodiment.

The display devices of FIGS. 8 and 9 are different from the display device of FIG. 5 described above in further including a cover layer 730, and the difference will be mainly described as follows.

As illustrated in FIGS. 8 and 9, the alignment mark layer 700 may include a cover layer 730. For example, the cover layer 730 may be disposed on the cover layer 730 and the second light blocking layer 712 to cover the pattern layer 720. In this example, at least a portion of the cover layer 730 may be disposed within the through hole 720a of the pattern layer 720, details of which will be described in subsequent sections. The cover layer 730 may protect the alignment mark 800 of the pattern layer 720 and improve adhesion between the pattern layer 720 and the light blocking layer 710. The cover layer 730 may include a transparent material so that the alignment mark 800 of the pattern layer 720 can be viewed. For example, the cover layer 730 may be made of transparent SiO₂.

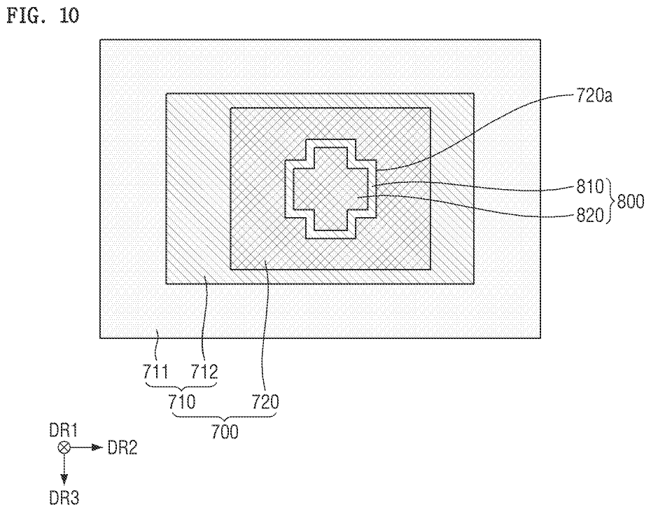

FIG. 10 is a plan view of an alignment mark layer 700 of a display device according to one embodiment.

The alignment mark layer 700 illustrated in FIG. 10 is different from the alignment mark layer 700 of FIG. 5 described above. The difference includes the alignment mark layer 700 in FIG. 10 has a different shape with the alignment mark 800. The specific distinctions and their implications are detailed in the following descriptions.

As illustrated in FIG. 10, the first mark 810 and the second mark 820 of the alignment mark 800 may each have a cross shape.

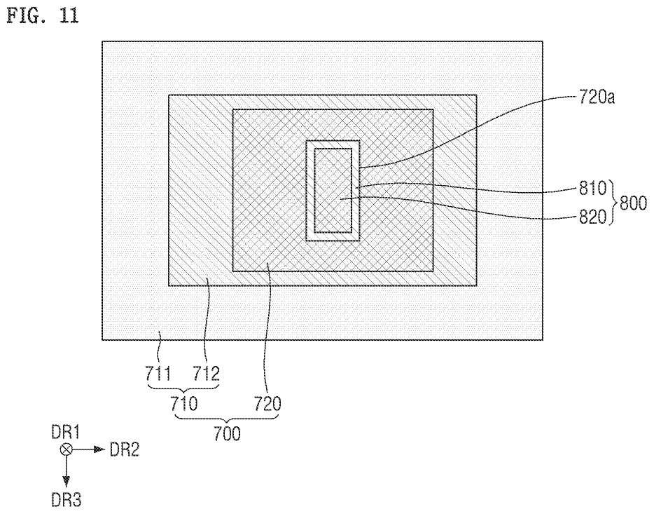

FIG. 11 is a plan view of an alignment mark layer 700 of a display device according to one embodiment.

The alignment mark layer 700 illustrated in FIG. 11 is different from alignment mark layer 700 of FIG. 5 described above. The difference includes the alignment mark layer 700 illustrated in FIG. 11 has a different shape with the alignment mark 800. The specific distinctions and their implications are detailed in the following descriptions.

As illustrated in FIG. 11, the first mark 810 and the second mark 820 of the alignment mark 800 may each have a rectangular shape.

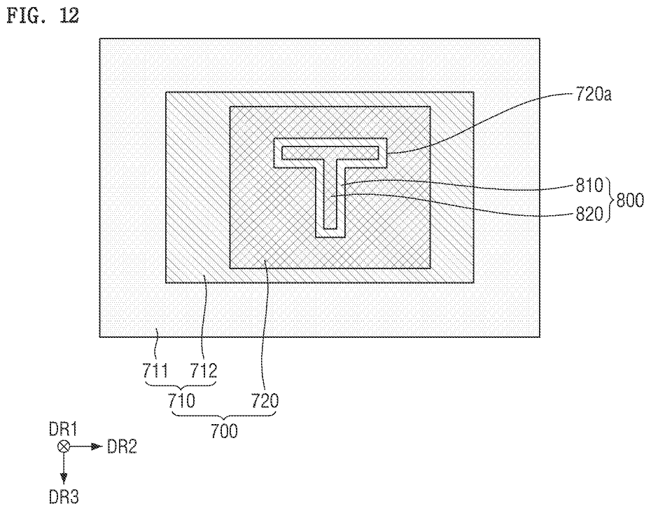

FIG. 12 is a plan view of an alignment mark layer 700 of a display device according to one embodiment.

The alignment mark layer 700 illustrated in FIG. 12 is different from the alignment mark layer 700 of FIG. 5 described above in having a different shape of the alignment mark 800. The specific distinctions and their implications are detailed in the following descriptions.

As illustrated in FIG. 12, the first mark 810 and the second mark 820 of the alignment mark 800 may each have a “T” shape.

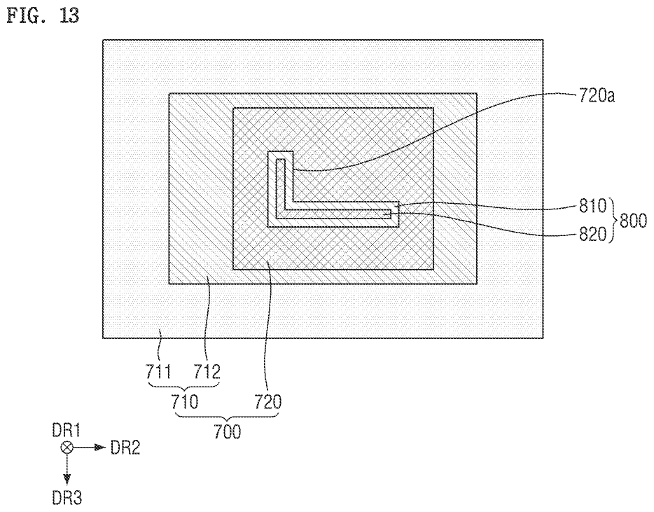

FIG. 13 is a plan view of an alignment mark layer 700 of a display device according to one embodiment.

The alignment mark layer 700 illustrated in FIG. 13 is different from the alignment mark layer 700 of FIG. 5 described above in having a different shape of the alignment mark 800. The specific distinctions and their implications are detailed in the following descriptions.

As illustrated in FIG. 13, the first mark 810 and the second mark 820 of the alignment mark 800 may each have a “L” shape.

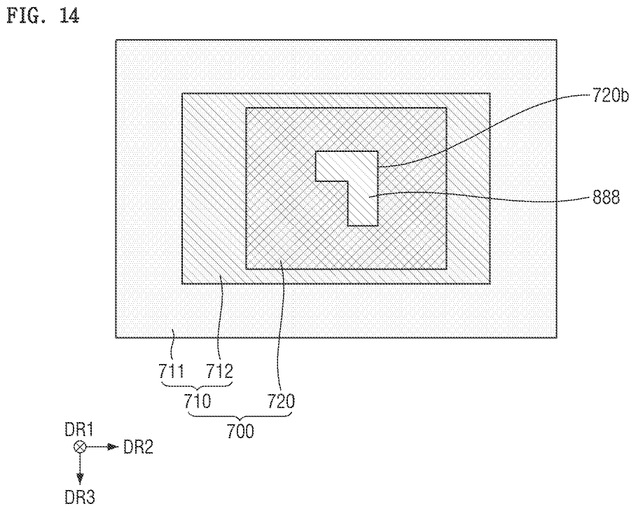

FIG. 14 is a plan view of an alignment mark layer 700 of a display device according to one embodiment.

The alignment mark layer 700 illustrated in FIG. 14 is different from the alignment mark layer 700 of FIG. 5 described above in having a different shape of an alignment mark 888. The specific distinctions and their implications are detailed in the following descriptions.

As illustrated in FIG. 14, an alignment mark 888 may be delineated by a through hole 720b penetrating the pattern layer 720. For example, as illustrated in FIG. 14, a layer (e.g., a second light blocking layer 712) adjacent to the pattern layer 720 in the first direction DR1 may be exposed through the through hole 720b of the pattern layer 720, and the portion of the second light blocking layer 712 exposed through the through hole 720b may be an alignment mark 888. The alignment mark 888 may be formed in an engraved shape.

The alignment mark 888 in FIG. 14 may have an “¬” shape. For example, the alignment mark 888 of FIG. 14 may have the same shape as the second mark 820 of FIG. 9 described above. However, while the second mark 820 of FIG. 9 is formed in an embossed shape, the alignment mark 888 of FIG. 14 may be formed in an engraved shape.

According to FIG. 14, since the color of the second light-shielding layer 712 (e.g., black) and the color of the pattern layer 720 (e.g., white) have high contrast, the visibility and recognition of the alignment mark 888, when exposed through the through hole 720b, may be increased.

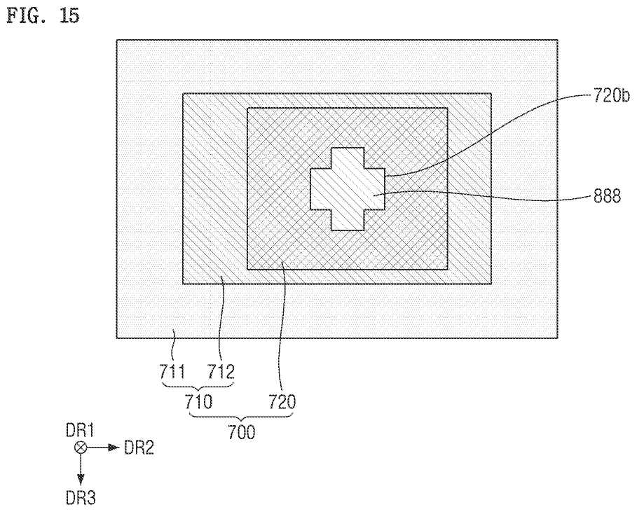

FIG. 15 is a plan view of an alignment mark layer 700 of a display device according to one embodiment.

The alignment mark layer 700 illustrated in FIG. 15 is different from the alignment mark layer 700 of FIG. 14 described above in having a different shape of an alignment mark 888. The specific distinctions and their implications are detailed in the following descriptions.

The alignment mark 888 in FIG. 15 may have a cross shape. For example, the alignment mark 888 of FIG. 15 may have the same shape as the second mark 820 of FIG. 10 described above. However, while the second mark 820 in FIG. 10 is formed in an embossed shape, the alignment mark 888 in FIG. 15 may be formed in an engraved shape.

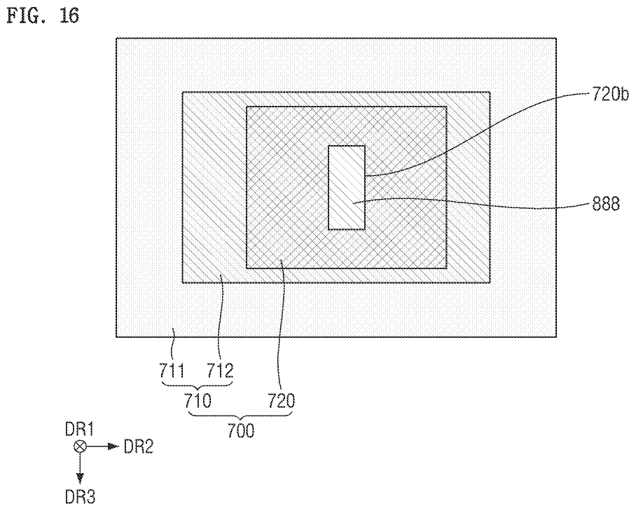

FIG. 16 is a plan view of an alignment mark layer 700 of a display device according to one embodiment.

The alignment mark layer 700 illustrated in FIG. 16 is different from the alignment mark layer 700 of FIG. 14 described above in having a different shape of an alignment mark 888. The specific distinctions and their implications are detailed in the following descriptions.

The alignment mark 888 in FIG. 16 may have a rectangular shape. For example, the alignment mark 888 of FIG. 16 may have the same shape as the second mark 820 of FIG. 11 described above. However, while the second mark 820 in FIG. 11 is formed in an embossed shape, the alignment mark 888 in FIG. 16 may be formed in an engraved shape. For example, the alignment mark 888 may be meticulously carved or etched into the surface, indicating a distinct, recessed pattern that provides differentiations such as tactile and visual differentiations.

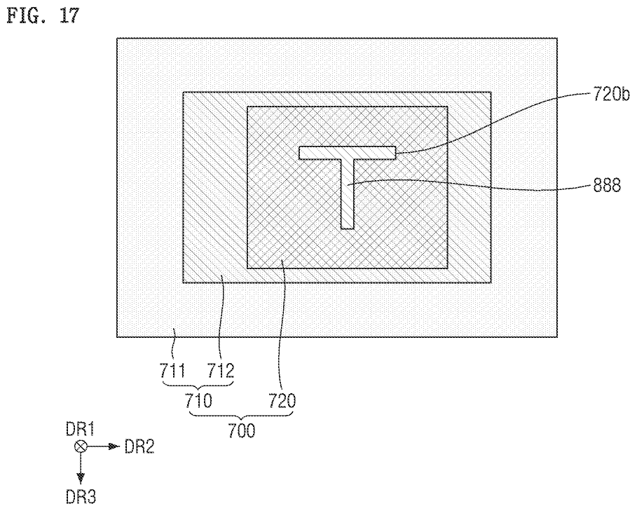

FIG. 17 is a plan view of an alignment mark layer 700 of a display device according to one embodiment.

The alignment mark layer 700 illustrated in FIG. 17 is different from the alignment mark layer 700 of FIG. 14 described above in having a different shape of an alignment mark 888. The specific distinctions and their implications are detailed in the following descriptions.

The alignment mark 888 in FIG. 17 may have a “T” shape. For example, the alignment mark 888 of FIG. 17 may have the same shape as the second mark 820 of FIG. 12 described above. However, while the second mark 820 in FIG. 12 is formed in an embossed shape, the alignment mark 888 in FIG. 17 may be formed in an engraved shape.

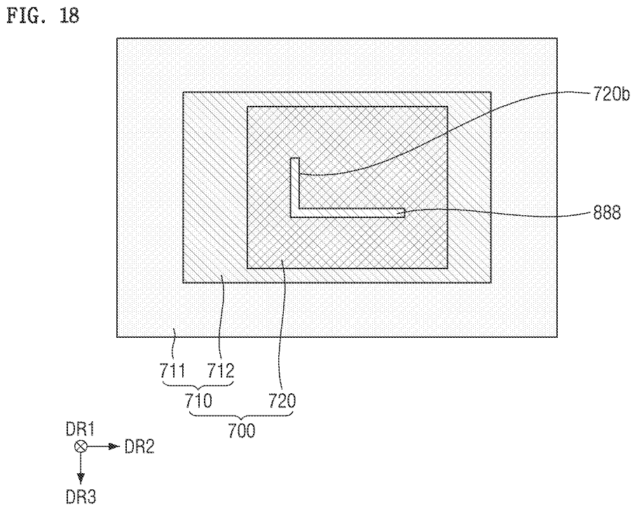

FIG. 18 is a plan view of an alignment mark layer 700 of a display device according to one embodiment.

The alignment mark layer 700 illustrated in FIG. 18 is different from the alignment mark layer 700 of FIG. 14 described above in having a different shape of an alignment mark 888. The specific distinctions and their implications are detailed in the following descriptions.

The alignment mark 888 in FIG. 17 may have a “L” shape. For example, the alignment mark 888 of FIG. 18 may have the same shape as the second mark 820 of FIG. 13 described above. However, while the second mark 820 in FIG. 13 is formed in an embossed shape, the alignment mark 888 in FIG. 18 may be formed in an engraved shape.

FIG. 19 is a diagram illustrating a lower surface of a display device according to one embodiment.

As illustrated in FIG. 19, the first light blocking layer 711 may be disposed along the lower surface of the flange portion 520. For example, as illustrated in FIG. 19, the first light blocking layer 711 may have a ring shape surrounding the display panel 400. For example, the ring shape may be a continuous circular or annular pattern surrounding the display panel 400.

The second light blocking layer 712 may be disposed on the first light blocking layer 711 and along the first light blocking layer 711. For example, the second light blocking layer 712 may have a ring shape surrounding the display panel 400.

The pattern layer 720 may be disposed on the second light blocking layer 712. For example, the pattern layer 720 may be disposed on the second light blocking layer 712 in a square or dot shape. For example, the squire shape indicates a pattern with four equal sides. For example, the dot shape indicates a small, round, or circular shape. In this example, a plurality of pattern layers 720 may be disposed on the second light blocking layer 712. FIG. 19 shows an example in which four pattern layers 720 are arranged on the upper, lower, left, and right sides of the display panel 400, respectively. For example, four pattern layers 720 are oriented in the third direction DR3, the reverse direction of the third direction DR3, the second direction DR2, and the reverse direction of the second direction DR2 based on the center of the display panel 400, respectively.

The plurality of pattern layers 720 may each have a through hole 720a like described above. An alignment mark 800 may be delineated by this through hole 720a.

According to some embodiments, the alignment mark 800 of FIG. 19 may be any one of the alignment marks 800 or 888 shown in FIGS. 6 and 9 to 18 described above. In addition, at least two of the plurality of alignment marks 800 of FIG. 19 may have different shapes. For example, at least two of the plurality of alignment marks 800 of FIG. 19 may include at least two of the alignment marks 800 or 888 shown in FIGS. 6 and 9 to 18.

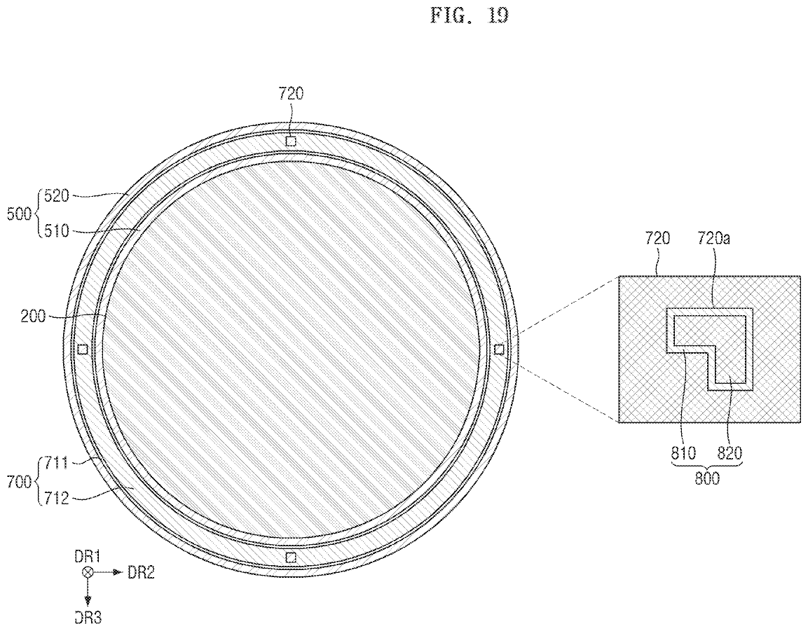

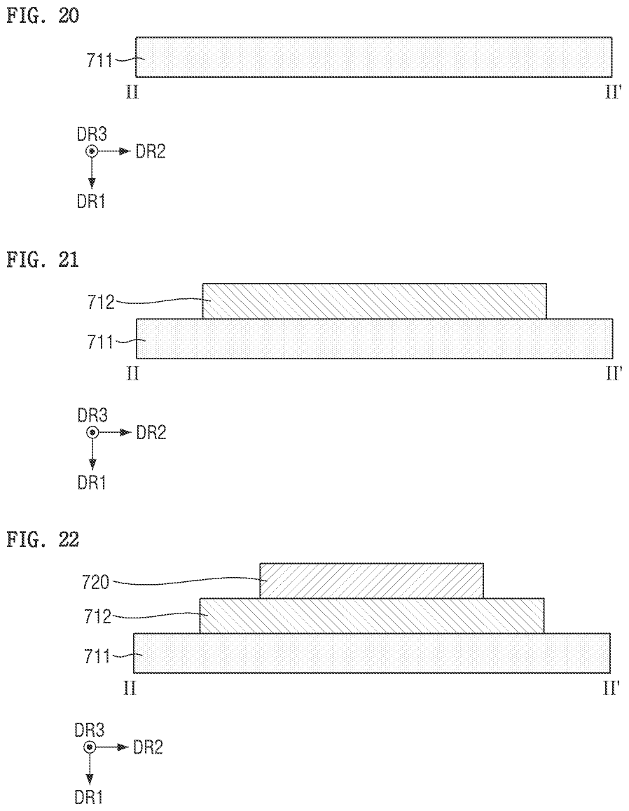

FIGS. 20 to 25 are cross-sectional views for describing processes of a manufacturing method of an alignment mark layer 700 of a display device according to one embodiment.

First, as illustrated in FIG. 20, an initial step involves the preparation of a first light blocking layer 711. This layer is subsequently positioned on the lower surface of a window member 500, which, in this case, corresponds to the underside of a flange portion 520.

Thereafter, as illustrated in FIG. 21, a second light blocking layer 712 may be disposed on the first light blocking layer 711.

Next, as illustrated in FIG. 22, a pattern layer 720 may be disposed on the second light blocking layer 712.

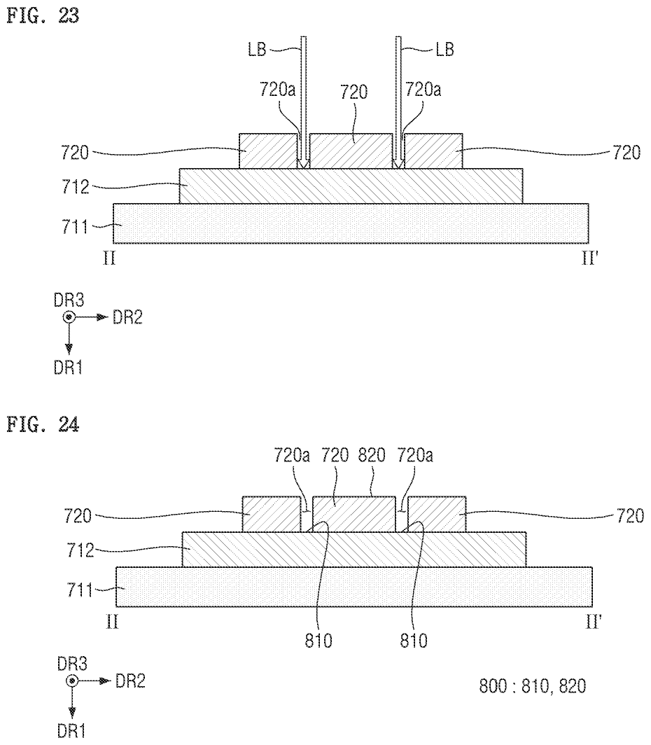

Subsequently, as illustrated in FIG. 23, a processing process which may be referred to as a patterning process, is carried out using a laser irradiation device. Specifically, laser beams emitted from the device are directed towards the pattern layer 720 in the reverse direction, allowing the laser beams, which may be referred to as laser beam LB, to pass through the pattern layer 720 and create a through hole 720a within the pattern layer 720.

Then, as illustrated in FIG. 24, an alignment mark 800 including a first mark 810 exposed through the through hole 720a and a second mark 820 surrounded and delineated by the first mark 810 of the through hole 720a may be formed. For example, an alignment mark 800 as illustrated in FIG. 9 may be formed. In this process, according to some embodiments, for example, an alignment mark 888 delineated by the through hole 720b as illustrated in FIG. 14 described above may be formed by irradiation of the laser beam LB.

Through this process, the pattern layer 720 undergoes precise patterning via the laser beam LB, allowing for the miniaturization of the alignment mark 800. By adjusting the intensity and scale of the laser beam LB, embodiments of the present disclosure enable the creation of small-sized alignment marks. In addition, because the pattern layer 720 is patterned by the laser beam LB, the shape of the alignment mark 800 can be precisely manufactured, and the position of the alignment mark 800 can be precisely controlled.

According to some embodiments, a window member 500 and a display panel 400 may be aligned based on the alignment mark 800 of the alignment mark layer 700.

Thereafter, the window member 500 may be attached to the display panel 400. For example, the lower surface of a body portion 510 included in the window member 500 may be attached to the display panel 400.

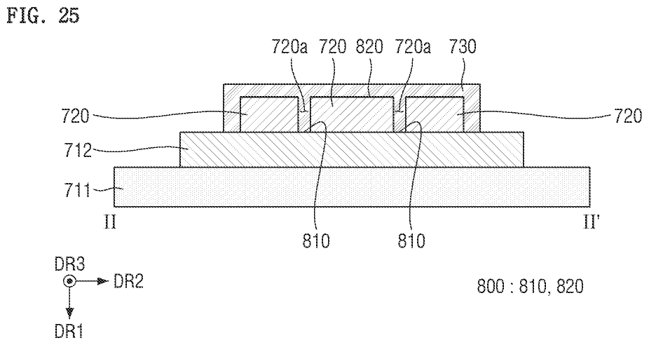

In some examples, a cover layer 730 may be further disposed on the pattern layer 720 having the through hole 720a as shown in FIG. 25, between the forming process and the alignment process (e.g., alignment process between the window member 500 and the display panel 400) of the pattern layer 720. In some examples, the cover layer 730 may be disposed on a second light blocking layer 712. In some examples, at least a portion of the cover layer 730 may be further disposed in the through hole 720a of the pattern layer 720.

It will be able to be understood by one of ordinary skill in the art to which the present disclosure belongs that the present disclosure may be implemented in other specific forms without changing the technical spirit or essential features of the present disclosure. Therefore, it is to be understood that the exemplary embodiments described above are illustrative rather than being restrictive in all aspects. It is to be understood that the scope of the present disclosure are defined by the claims rather than the detailed description described above and all modifications and alterations derived from the claims and their equivalents fall within the scope of the present disclosure.

What is claimed is:

1. A display device comprising:
a display panel;
a window member disposed on the display panel; and
an alignment mark layer disposed on a lower surface of the window member,
wherein the alignment mark layer comprises:
a light blocking layer disposed on the lower surface of the window member; and
a pattern layer disposed on the light blocking layer, wherein the pattern layer includes a through hole penetrating the pattern layer and exposing the light blocking layer.

2. The display device of claim 1,
wherein the light blocking layer comprises a plurality of layers.

3. The display device of claim 1,
wherein the light blocking layer comprises:
a first light blocking layer disposed on the lower surface of the window member; and
a second light blocking layer disposed on the first light blocking layer.

4. The display device of claim 3,
wherein a width of the second light blocking layer is smaller than a width of the first light blocking layer.

5. The display device of claim 4,
wherein a width of the pattern layer is smaller than the width of the second light blocking layer.

6. The display device of claim 1,
wherein a color of the light blocking layer and a color of the pattern layer are different from each other.

7. The display device of claim 1,
wherein the light blocking layer has a black-based color, and
wherein the pattern layer has a white-based color.

8. The display device of claim 1,
wherein an alignment mark of the alignment mark layer comprises a light blocking layer exposed through the through hole of the pattern layer.

9. The display device of claim 8,
wherein the alignment mark has one shape among a “¬” shape, a cross shape, a rectangular shape, a “T” shape and an “L” shape.

10. The display device of claim 1,
wherein, from a plan view, the through hole forms a closed curve shape.

11. The display device of claim 10,
wherein an alignment mark of the alignment mark layer comprises a first mark and a second mark, wherein the first mark and the second mark are disposed on different layers,
wherein the first mark comprises the light blocking layer exposed by the through hole having the closed curve shape, and
wherein the second mark comprises the pattern layer exposed and delineated by the through hole having the closed curve shape.

12. The display device of claim 11,
wherein the first and second marks each have one shape among a “¬” shape, a cross shape, a rectangular shape, a “T” shape and an “L” shape.

13. The display device of claim 1,
wherein the light blocking layer comprises a carbon-based light blocking material including carbon black, a dye, a pigment, or a combination thereof.

14. The display device of claim 1,
wherein the pattern layer is formed of ink comprising a material, pigment, or dye of white color.

15. The display device of claim 1,
wherein the alignment mark layer further comprises a cover layer disposed on the pattern layer.

16. The display device of claim 15,
wherein the cover layer includes transparent SiO₂.

17. The display device of claim 1,
wherein the window member comprises:
a body portion, wherein the display panel is disposed on the body portion; and
a flange portion disposed on an edge of the body portion.

18. The display device of claim 17,
wherein the alignment mark layer is disposed on the lower surface of the flange portion.

19. A method of manufacturing a display device comprising:
disposing a first light blocking layer on a lower surface of a window member;
disposing a second light blocking layer on the first light blocking layer;
disposing a pattern layer on the second light blocking layer; and
forming an alignment mark by forming a through hole in the pattern layer to expose the second light blocking layer.

20. The method of claim 19,
wherein first and second light blocking layers each have black color, and
wherein the pattern layer has white color.

21. The method of claim 19,
wherein the alignment mark comprises a light blocking layer exposed through the through hole of the pattern layer, and wherein forming the through hole in the pattern layer is performed with a laser beam.

22. The method of claim 19,
wherein, in a plan view, the through hole form a closed curve shape.

23. The method of claim 22,
wherein the alignment mark comprises a first mark and a second mark, wherein the first mark and the second mark are disposed on different layers,
wherein the first mark comprises a light blocking layer exposed by the through hole having the closed curve shape, and
wherein the second mark comprises the pattern layer surrounded and delineated by the through hole having the closed curve shape.

24. The method of claim 19, further comprising disposing a cover layer on the pattern layer.

25. The method of claim 19, further comprising aligning the window member and a display panel based on the alignment mark; and
attaching the window member and the display panel.

26. A method of manufacturing a display device comprising:
disposing a first light blocking layer on a lower surface of a window member on a display panel;
disposing a second light blocking layer on the first light blocking layer;
disposing a pattern layer on the second light blocking layer;
forming an alignment mark by forming a through hole in the pattern layer to expose the second light blocking layer; and
applying a cover layer on the pattern layer.
